(19) United States
(12) Patent Application Publication
(10) Pub. No.: US 2010/0188083 A1
(43) Pub. Date: Jul. 29, 2010

(54) MAGNETIC RESONANCE IMAGING SYSTEM AND METHOD FOR STABILIZING THE TEMPERATURE OF THE MAIN MAGNET THEREIN

(76) Inventors: Kai Cao, Beijing (CN); Jiabin Yao, Beijing (CN)

Correspondence Address: PATRICK W. RASCHE (20459);ARMSTRONG TEASDALE LLP, ONE METROPOLITAN SQUARE, SUITE 2600, ST. LOUIS, MO, 63102-2740, US

(21) Appl. No.: 12/692,107

(22) Filed: Jan. 22, 2010

(30) Foreign Application Priority Data
Jan. 24, 2009 (CN) 200910005996.4

(51) Int. Cl. G01R 33/44

(52) U.S. Cl. 324/307; 324/318

(57) ABSTRACT

A magnetic resonance imaging system includes a display device and a host. The host includes a power cabinet having a gradient driver including a gradient controller and a gradient amplifier, and a radio frequency (RF) driver including a RF controller and a RF amplifier. The host also includes a magnetic field generating device including a pair of main magnets with opposite polarities that face each other and are spaced apart from each other, a magnet column that forms a magnetic circuit for the main magnets, and a gradient coil unit, wherein the power cabinet is provided adjacent to the outside of the magnet column of the magnetic field generating device, and wherein the power cabinet is configured to heat said main magnets by transferring heat produced in the power cabinet to the main magnets.

### CROSS REFERENCE TO RELATED APPLICATIONS

This application claims the benefit of Chinese Patent Application No. 200910005996.4 filed Jan. 24, 2009, which is hereby incorporated by reference in its entirety.

### BACKGROUND OF THE INVENTION

The embodiments described herein relate to a Magnetic Resonance Imaging (MRI) technique, in particular to the heating of magnet and cooling of electrical parts.

### BACKGROUND OF THE INVENTION

An MRI system is a system which obtains the magnetic resonance signals of a human body under a magnetic field based on the nuclear magnetic resonance principle and reconstructs an image based on said magnetic resonance signals. An MRI system usually comprises a main magnet, a gradient coil, an electrical part, a radio frequency (RF) coil, which are used for the generation, detection and encoding of the MR signals. The main magnet is generally a permanent magnet, an electromagnetic or a superconducting magnet, and it is a permanent magnet in this application. An MRI system further comprises an analog converter, a computer, a magnetic disk, a magnetic tape drive, etc., which are used for data processing and image reconstruction, display and storing. The main magnet is used for generating a highly uniform and stable static magnetic field (which is also called main magnetic field, and for short, magnetic field), and it directly affects the strength, uniformity and stability of the magnetic field and thus the image quality of MRI. The gradient coil is used for modifying the main magnetic field to generate a gradient magnetic field. Although the strength of the gradient magnetic field is only one several-hundredth of that of the main magnetic field, the gradient magnetic field makes it possible to perform three-dimensional spatial encoding of the MR signals of a human body. The gradient coil may consist of three gradient magnetic field coils of X, Y and Z and have a drive to rapidly change the direction and strength of the magnetic field during scan so as to quickly finish the three-dimensional encoding. The RF coil is used to emit the RF pulse that excites the spin of the hydrogen atomic nucleus within a subject and to receive the MR signals generated from the subject.

In the MRI system, generating and maintaining a highly stable and uniform magnetic field is a key technique for guaranteeing good MRI image quality. However, the main magnet will manifest different characteristics in different time and environment. The temperature change of the permanent magnet will influence the stability of the strength of the magnetic field generated thereby, so the permanent magnet usually operates in a temperature higher than the room temperature in order to prevent it from being influenced by the change in the room temperature.

Various methods have been proposed in the prior art to heat the permanent magnet and to keep it in a constant temperature. For example, one of the methods places a surface heater at the outer surface of the permanent magnet and uses a temperature controller and a temperature sensor to monitor and control the temperature of the permanent magnet, so that the permanent magnet could operate within a prescribed range of temperature.

In addition, the electrical parts and gradient coil, etc. in the MRI system will produce a lot of heat during operation. In order to prevent the operating performance of the electrical parts and the permanent magnet from being affected by the high temperature, a cooling system, such as a cooling system formed by air or liquid (e.g. water) is usually provided for them in the prior art, so that heat could be dissipated from the MRI system.

Therefore, in a current open MRI system, the permanent magnet and the electrical parts are usually separated from each other. In order to keep the temperature of the permanent magnet stable, a heating system has to be provided thereto. And in order to dissipate the heat produced during operation of the electrical parts, a cooling system has to be provided thereto. As a result, there are both a heating system and a cooling system in the MRI system, which not only wastes energy but also increases the complexity of the whole system.

### BRIEF DESCRIPTION OF THE INVENTION

Embodiments described herein provide a magnetic resonance imaging system and a method for stabilizing the main magnet temperature in the magnetic resonance imaging system. According to one aspect of the present invention, a magnetic resonance imaging system is provided, which comprises a host and a display device. The host comprises a power cabinet and a magnetic field generating device. The power cabinet comprises a gradient driver including a gradient controller and a gradient amplifier and a RF driver including a RF controller and a RF amplifier. The magnetic field generating device comprises a pair of main magnets with opposite polarities that face each other and are spaced apart from each other, a magnet column that forms a magnetic circuit for the main magnets and a gradient coil unit. The power cabinet is provided adjacent to the outside of the magnet column of the magnetic field generating device, and can be used as a heating device of the main magnets by transferring the heat produced therein to the main magnets.

In the MRI system according to the present invention, such components as the gradient controller, the RF controller, etc. in the power cabinet that are sensitive to the magnetic field are arranged far away from the magnetic field generating device, while such high power, magnetic field non-sensitive components as the gradient amplifier, the RF amplifier, etc. are arranged close to the outside of the magnet column.

In the MRI system according to the present invention, the power cabinet further comprises a heat sink for transferring the heat produced in the power cabinet to the main magnets.

In the MRI system according to the present invention, one end of the heat sink can be arranged at a side of the high power, magnetic field non-sensitive components (e.g. the gradient amplifier, RF amplifier) in the power cabinet that is close to the magnetic field generating device, so that the heat produced by the operation of said component can be transferred to the main magnets through the heat sink. In addition, the other end of the heat sink can be arranged close to the outside surface of the magnet column.

In the MRI system according to the present invention, in order to reduce the influence to the electronic parts in the power cabinet by the magnetic field of the main magnets, the magnetic field strength at the rear end of the main magnets is limited within an acceptable range.

In the MRI system according to the present invention, the magnetic field generating device further comprises a temperature monitoring means for detecting the temperature of the main magnet. The power cabinet further comprises a temperature controller and a cooling device. Said temperature controller is used to control the activation and deactivation of the cooling device according to the temperature provided by the temperature monitoring means. When the main magnets do not need to be heated, the cooling device is activated to dissipate the heat produced by the power cabinet and the magnetic field generating device out of the host. When the main magnets need to be heated, the cooling device is deactivated. The temperature monitoring means can be a temperature sensor inserted into the main magnet.

In the MRI system according to the present invention, the temperature controller is also connected to the gradient amplifier to control the activation and deactivation of the gradient amplifier according to the temperature provided by the temperature monitoring means when the MRI system is in a non-operating state. When the main magnets need to be heated, the temperature controller activates the gradient amplifier, so that the heat generated by the operation of the gradient amplifier is transferred to the main magnet. Meanwhile, the gradient amplifier supplies electric current to the gradient coil unit to make it operate so that the heat produced by operation of the gradient coil unit is also used to heat the main magnets. When the main magnets do not need to be heated, the temperature controller controls the gradient amplifier to stop operating.

In the MRI system according to the present invention, during the operation of the MRI system, when the temperature controller determines that the main magnets need to be heated according to the temperature transferred from the temperature monitoring means, the heat produced by operation of the gradient amplifier and the RF amplifier is transferred to the main magnet; when the temperature controller determines that the main magnets do not need to be heated, the cooling device dissipates the heat produced by operation of the gradient amplifier and the RF amplifier as well as the heat in the magnetic field generating device out of the host.

According to a second aspect of the present invention, a method for stabilizing the main magnet temperature in the MRI system is provided. The MRI system comprises a power cabinet and a magnetic field generating device. The power cabinet comprises a gradient driver including a gradient controller and a gradient amplifier, and a RF driver including a RF controller and a RF amplifier. The magnetic field generating device comprises a pair of main magnets with opposite polarities that face each other and are spaced apart from each other, a magnet column that forms a magnetic circuit for the main magnets and a gradient coil unit. Said method comprises arranging the power cabinet to be adjacent to the outside of the magnet column of the magnetic field generating device, so that the heat produced in the power cabinet is transferred to the main magnets.

In said method according to the present invention, such components as the gradient controller, the RF controller, etc. in the power cabinet that are sensitive to the magnetic field are arranged far away from the magnetic field generating device, while such high power, magnetic field non-sensitive components as the gradient amplifier, the RF amplifier, etc. are arranged close to the outside of the magnet column.

In said method according to the present invention, the heat produced in the power cabinet can be transferred to the main magnet through a heat sink. Said heat sink can be arranged at a side of the high power, magnetic field non-sensitive components in the power cabinet that is close to the magnetic field generating device, so that the heat produced by operation of said components can be transferred to the main magnets through the heat sink. In addition, the heat sink can be arranged close to the outside surface of the magnet column. Moreover, the arrangement of the heat sink can meet both of the above-mentioned conditions.

In said method according to the present invention, the magnetic field strength at the rear end of the main magnets is limited within an acceptable range so as to reduce the influence to the electronic parts in the power cabinet by the magnetic field.

In said method according to the present invention, the temperature of the main magnets is monitored when the MRI system is in a non-operating state. And when the main magnets need to be heated, the gradient amplifier is activated, so that the heat produced thereby is transferred to the main magnet. Meanwhile, the gradient amplifier supplies electric current to the gradient coil unit, so that the heat produced by operation of the gradient coil unit is also used to heat the main magnet. When the main magnets do not need to be heated, the gradient amplifier is deactivated. Alternatively, when the temperature in the power cabinet or the temperature in the magnetic generating device is too high, the heat therein can be dissipated out of the host by the cooling system formed by air or water.

In said method according to the present invention, during the operation of the MRI system, the heat produced by operation of the gradient amplifier and the RF amplifier is transferred to the main magnet when the main magnets need to be heated, and the heat produced by operation of the gradient amplifier and the RF amplifier as well as the heat in the magnetic field generating device is dissipated out of the MRI system when the main magnets do not need to be heated. The present invention integrates the separated power cabinet and magnetic field generating device in the existing MRI system together, uses the heat produced by the power cabinet to heat the permanent magnet and thus cools the power cabinet. Meanwhile, the number of cables in the power cabinet is reduced, therefore the MRI system of the present invention has the merits of simplified structure, energy saving and lower system cost, moreover, the reliability of the whole system is improved. In addition, the MRI system according to the present invention is designed to be miniaturized, so it has smaller footprint, consumes less time for installing and is easy to be implemented.

### BRIEF DESCRIPTION OF THE DRAWINGS

FIG. 1 shows a block diagram of the structure of the MRI system according to the present invention;

FIG. 2 shows the operating mechanism of the MRI system according to the present invention during scanning;

FIG. 3 shows the operating mechanism of the MRI system according to the present invention when it does not scan.

### DETAILED DESCRIPTION OF THE INVENTION

Aspects of the present invention will be further described in detail below by means of various embodiments, but the invention is not limited to the embodiments described herein.

Embodiments of the present invention change the structure of the MRI system of the prior art, that is, some embodiments position the power cabinet having electrical parts of an MRI system installed therein to be close to the magnetic field generating device that generates a magnetic field, for example, by conventional mechanical connection means (e.g. bolts, etc.), so that the heat produced by the electrical parts in the power cabinet can be used to heat the permanent magnet. Therefore there is no need to provide a cooling device dedicated to the power cabinet in the MRI system and there is no need to provide a heater for the permanent magnet, either. As a result, the object of sufficiently using energy and simplifying the system structure is achieved, meanwhile, the MRI system has a compact structure, simple installation and low cost.

In the above embodiment of the present invention, the influence to the electrical parts in the power cabinet by the magnetic field is considered. One way is to limit the magnetic field strength at the rear end of the main magnet to be within an acceptable range (e.g. within 30 Gauss) so as to reduce the influence to the electronic parts in the power cabinet by the magnetic field. Another way is to arrange the components in the power cabinet that are sensitive to the magnetic field far away from the main magnet, and arrange the high-power, magnetic field non-sensitive components to be close to the outside surface of the magnet column in the magnetic field generating device. In the exemplary embodiment, a combination of the above two ways is adopted.

When the MRI system is in a non-operating state, the temperature of the main magnet is monitored. When the main magnets need to be heated, activating at least one high-power, magnetic field non-sensitive component in the power cabinet, so that the heat produced thereby is transferred to the main magnet; when the main magnets do not need to be heated, deactivating said at least one high-power, magnetic field non-sensitive component in the power cabinet. For instance, when the main magnets need to be heated, the gradient amplifier in the power cabinet can be activated to make it produce heat, meanwhile, the gradient amplifier supplies electric current to the gradient coil unit to make it operate and produce heat, and said two kinds of heat are used to heat the main magnet. Alternatively, a heater can be arranged at the circumferential of the main magnet to heat it. In addition, any combination of the above-mentioned ways can be adopted, or a combination of above-mentioned ways and other ways in the prior art can be adopted.

During the operation of the MRI system, the heat produced by the high-power, magnetic field non-sensitive components is transferred to the main magnet when the main magnets need to be heated, and the heat produced by the high-power, magnetic field non-sensitive components as well as the heat in the magnetic field generating device are dissipated out of the MRI system when the main magnets do not need to be heated. Preferably, the high-power, magnetic field non-sensitive components are a gradient amplifier and a RF amplifier.

Embodiments of the present invention will be described in detail below with reference to the drawings, but these embodiments are not intended to limit the present invention. The same components in different drawings are denoted by the same reference signs.

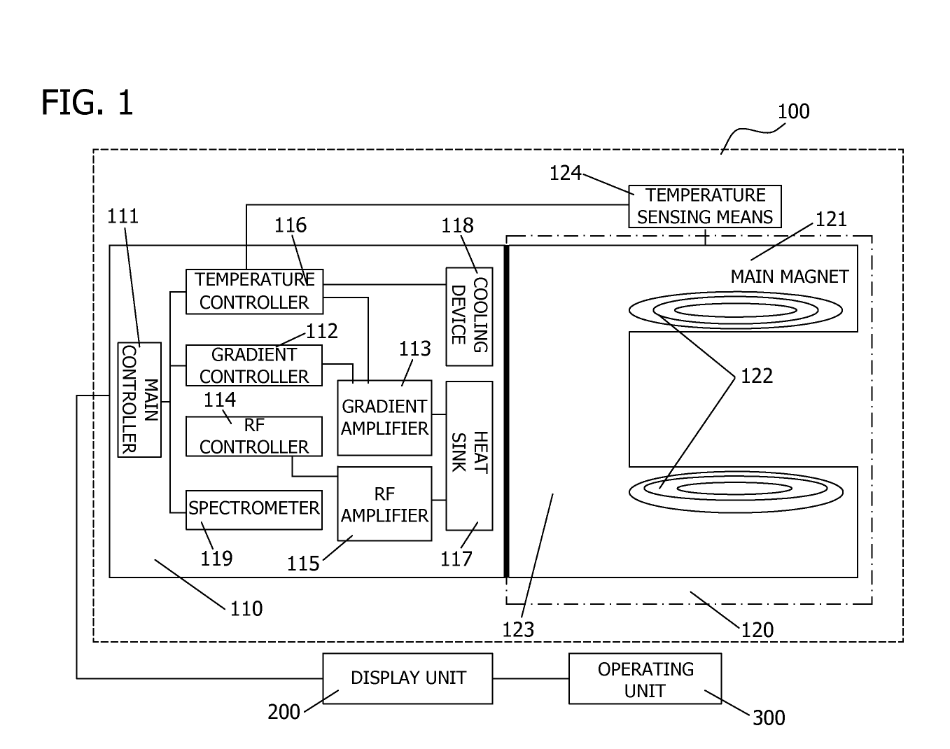

FIG. 1 shows a block diagram of the structure of the MRI system according to the present invention. As shown in FIG. 1, the MRI system according to the present invention comprises a host 100 (the portion enclosed by the dashed lines in FIG. 1), a display unit 200 and an operating unit 300. Since the display unit 200 and the operating unit 300 can be realized by the existing techniques, for example, the display unit 200 can be realized by a computer and the operating unit 300 can be the keyboard of the computer or an operating panel dependent from the computer, detailed descriptions of them are omitted herein.

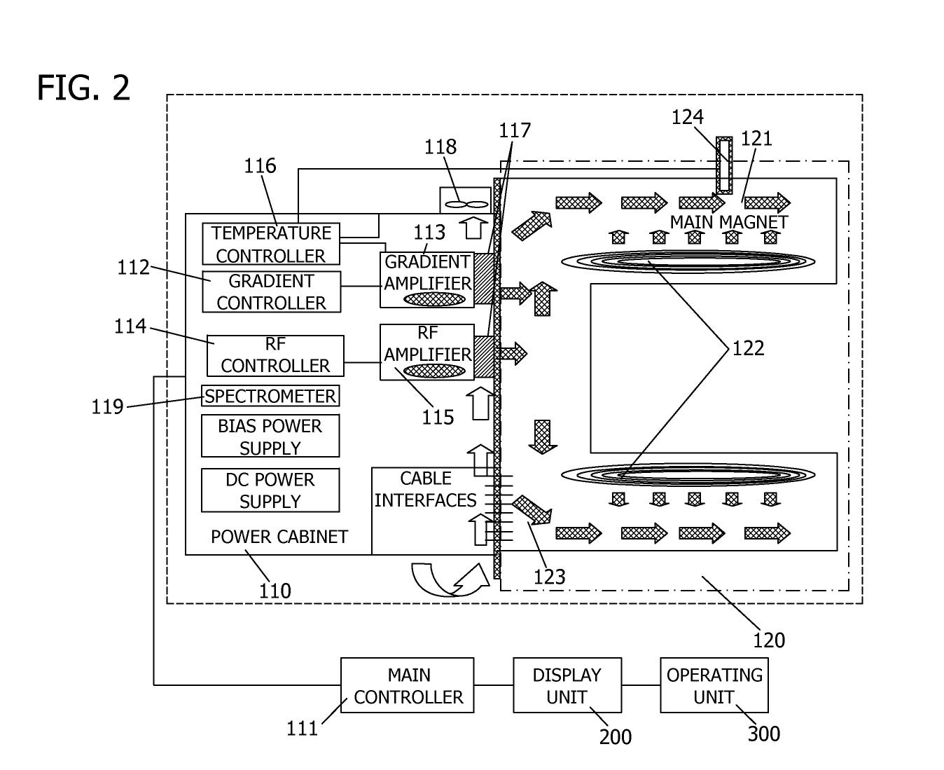

FIG. 1 shows that the host 100 of the present invention integrates the power cabinet 110 with the magnetic field generating device 120 (the portion enclosed by the dash-and-dot lines in FIG. 1) instead of spacing them apart. The magnetic field generating device 120 comprises a pair of main magnets 121 with opposite polarities that face each other and are spaced apart from each other, a magnet column 123 that forms a return passage for the magnetic flux of the main magnets 121, a gradient coil unit 122 and a RF coil unit (not shown), etc. provided within said pair of main magnets 121. The main magnets 121 are permanent magnets. The magnet column 123 may be formed of ferromagnetic material, such as soft iron, which has substantially a C-shape, but is not limited to the C-shape. The gradient coil unit 122 and RF coil unit can be respectively arranged on the pole surfaces of said pair of main magnets 121, while only the gradient coil unit 122 arranged on the pole surface of the main magnet 121 is shown herein. In addition, a temperature sensing means 124 is provided at the side of the magnetic field generating device 120 for monitoring the temperature of the main magnets 121. The temperature sensing means 124 can be, for example, a temperature sensor, which can be either provided on the outer surface of the main magnets 121 or inserted into the main magnets (as shown in FIG. 2).

The power cabinet 110 is immediately adjacent to the outer side surface of the magnet column 123 of the magnetic field generating device 120. The power cabinet 110 can be connected to the magnetic field generating device 120 by a conventional mechanical connection means such as a screw and a nut.

The power cabinet 110 comprises a main controller 111, a gradient controller 112, a gradient amplifier 113, a RF controller 114, a RF amplifier 115, a temperature controller 116, a heat sink 117, a cooling device 118, a spectrometer 119, etc.

The gradient controller 112 and the gradient amplifier 113 form a gradient driver which supplies driving signals to the gradient coil unit 122 so as to generate a gradient magnetic field. The RF controller 114 and the RF amplifier 115 form a RF driver which supplies driving signals to the RF coil unit to emit RF (radio frequency) pulse so as to excite the spin of the hydrogen atomic nucleus in the inspected subject.

When the main magnets need to be heated, the heat sink 117 is used to transfer the heat produced by the gradient amplifier 113 (when the MRI system is in a non-operating state) or the heat produced by the gradient amplifier 113 and the RF amplifier 115 (when the MRI system is in an operating state) to the main magnets 121. When the main magnets do not need to be heated, the heat sink 117 dissipates the heat produced by the gradient amplifier 113 or the heat produced by the gradient amplifier 113 and the RF amplifier 115 as well as the heat in the magnetic field generating device 120 out of the host 100 through the cooling device 118. The heat sink 117 may be cooling plates which are placed behind each of the gradient amplifier 113 and the RF amplifier 115, or there could be one cooling plate placed behind the gradient amplifier 113 and the RF amplifier 115. The heat sink 117 is arranged to be abut on the outside surface of the magnet column 123. The cooling device 118 may be a ventilating fan or a device that uses air or liquid (e.g. water) to cool and dissipate heat. The cooling device 118 is connected to the temperature controller 116. The temperature controller 116 controls the activation and deactivation of the cooling device 118 according to the sensed temperature of the main magnets 121 as transferred from the temperature monitoring means 124. When the main magnets 121 need to be heated, the cooling device 118 is deactivated, while when the main magnets do not need to be heated, the cooling device 118 is activated. In addition, the temperature controller 116 can also be connected to the gradient amplifier 113 to activate it when the MRI system of the present invention is in a non-operating state (i.e. when no scan is performed) and the main magnets 121 need to be heated, so that the gradient amplifier 113 operates and produces heat. The heat produced by the gradient amplifier 113 is transferred to the main magnet 121 through the heat sink 117. Meanwhile, the gradient amplifier 113 may supply current to the gradient coil unit 122 to make it operate to produce heat. The heat produced by both of the gradient amplifier 113 and the gradient coil unit 122 are used to heat the permanent magnets. When the main magnets 121 that are in a non-operating state do not need to be heated, the temperature controller 116 controls the gradient amplifier 113 to be deactivated, that is, to make it stop operating, and makes the gradient coil unit 122 stop operating at the same time. The main controller 111 is used to control the components in the power cabinet 110 and process the received magnetic resonance signals as generated by the human body so as to reconstruct an image to be displayed on the display unit 200. The spectrometer 119 processes the received magnetic resonance signals as generated by the human body.

Since the power cabinet 110 and the magnetic field generating device 120 are very close to each other, in order to reduce the influence of the magnetic field to the electronic components in the power cabinet 110, one way is to limit the magnetic field strength at the rear end of the permanent magnet within an acceptable range, preferably within 30 Gauss, and this can be realized by making the vertical portion of the magnet column 123 as shown in FIG. 1 to be thick enough in the horizontal direction. The other way is to arrange the magnetic field sensitive components (e.g. the gradient controller 112, the RF controller 114, the temperature controller 116, the spectrometer 119, etc.) in the power cabinet 110 to be far away from the main magnets 121, and arrange the high-power, magnetic field non-sensitive components (e.g. the gradient amplifier 113, the RF amplifier 115, etc.) to be close to the outside surface of the magnet column 123.

Furthermore, to keep the temperature of the main magnets 121 stable, a plurality of heating fins or surface heaters can be arranged on the surface of the main magnets 121. Of course, other heating methods or devices in the prior art can also be used.

In addition, in order to keep the temperature of the main magnets 121 to be not too high, a cooling device can be provided in the magnetic field generating device so that it can be activated when the main magnets 121 need to be cooled. Any methods and devices for cooling the main magnets 121 in the prior art are applicable to the present invention.

The operating mechanisms of the MRI system of the present invention in the operating state and the non-operating state will be described respectively in detail hereinafter so as to make the present invention apparent. However, said ways are merely the preferred ways of implementing the present invention, and the specific components therein are merely preferred components for achieving the present invention which is not limited thereto.

FIG. 2 shows the operating mechanism of the MRI system of the present invention during scanning. As shown in FIG. 2, the power cabinet 110 housing the electrical parts of an MRI system is connected to the magnetic field generating device 120 through a bolt. In the power cabinet 110, such magnetic field sensitive components as gradient controller 112, the RF controller 114, the temperature controller 116, the spectrometer 119, a bias power supply for providing a bias voltage to coils, a DC power supply, etc. are arranged far away from the magnet column 123, while such high-power, magnetic field sensitive components as the gradient amplifier 113 and the RF amplifier 115 are arranged close to the outside surface of the magnet column 123. Heat sink 117 includes a cooling plate arranged on a side of each of the gradient amplifier 113 and the RF amplifier 115 that is close to the magnetic field generating device 120, and both of the cooling plates of heat sink 117 are abut on the outside surface of the magnet column 123. At the side of the magnetic field generating device 120, the temperature sensor 124 is inserted into the permanent magnet 121.

When the MRI system as shown in FIG. 2 starts to scan, the gradient amplifier 113 and the RF amplifier 115 in the power cabinet 110 operate to produce heat. The heat produced by said gradient amplifier 113 and RF amplifier 115 are transferred to the permanent magnet 121 through the cooling plates of heat sink 117 arranged behind them respectively and the magnet column 123. Meanwhile, the gradient amplifier 113 transfers driving signals to the gradient coil unit 122 to supply electric current thereinto, so that it operates to produce heat. Therefore, the permanent magnets 121 are now heated by the heat from the both. The arrows in deep color in the magnetic field generating device 120 in FIG. 2 indicate the heat transferred to the permanent magnets 121 from the two cooling plates of heat sink 117 and the gradient coil unit 122. The temperature sensor 124 monitors the temperature of the permanent magnet in real time and transfers it to the temperature controller 116. Usually, when fabricating an MRI system, a normal operating temperature (e.g. 32.5° C.), an upper limit operating temperature and a lower limit operating temperature are set for the permanent magnets. When the permanent magnets operate in a temperature between the upper limit operating temperature and the lower limit operating temperature, the imaging quality of the MRI system can be guaranteed. However, once the permanent magnets operate in a temperature higher than the upper limit operating temperature or lower than the lower limit operating temperature, the imaging quality of the MRI system will be degraded. When the temperature sensor 124 monitors that the temperature of the permanent magnet 121 is close to or exceeds a predetermined upper limit regulating temperature that is between the upper limit operating temperature and the normal operating temperature (and that can be equal to the upper limit operating temperature), the temperature controller 124 triggers a fan of cooling device 118 to operate so as to dissipate the heat produced in the power cabinet 110, especially by the gradient amplifier 113 and the RF amplifier 115 directly out of the host 100, thus the heat will not be transferred to the permanent magnets 121 through the cooling plates of heat sink 117. The white arrows at the right side of the power cabinet in FIG. 2 indicate the movement of the airflow from the fan. When the temperature sensor 124 monitors that the temperature of the permanent magnet 121 is close to or lower than a predetermined lower limit regulating temperature that is between the lower limit operating temperature and the normal operating temperature (and that can be equal to the lower limit operating temperature), it makes the fan of cooling device 118 to stop operating.

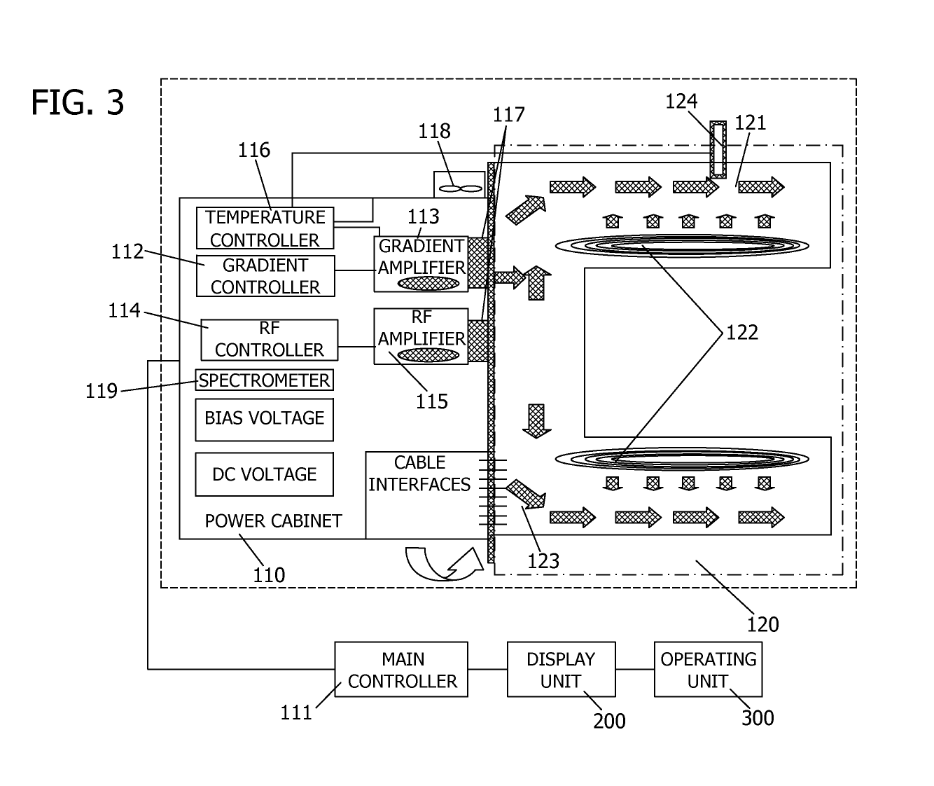

FIG. 3 shows the operating mechanism of the MRI system of the present invention when scanning is not performed. As shown in FIG. 3, when the MRI system is not scanning, the temperature controller 116 controls the activation and deactivation of the gradient amplifier 113 according to the temperature feedback of the permanent magnets 121 sensed by the temperature sensor 124 so as to keep the temperature of the permanent magnets 121 stable. When the temperature sensor 124 senses that the temperature of the permanent magnets 121 is close to or lower than the predetermined lower limit regulating temperature, the gradient amplifier 113 is activated to operate to produce heat, meanwhile, the gradient amplifier supplies electric current to the gradient coil unit 122 to make it operate to produce heat. All these heat are transferred through the cooling plates of heat sink 117 and the magnet column 123 to the permanent magnets 121 to heat it. The arrows in deep color in the magnetic field generating device 120 in FIG. 3 indicate the heat transferred to the permanent magnets 121 from the cooling plates of heat sink 117 behind the gradient amplifier and the gradient coil unit 122. The value of the electric current in the gradient coil unit 122 is determined based on the temperature feedback from the temperature sensor. When the temperature sensor 124 senses that the temperature of the permanent magnets 121 is close to or higher than the predetermined upper limit regulating temperature, the gradient amplifier 113 is deactivated, so that both the gradient amplifier 113 and the gradient coil unit 122 stop operating.

Alternatively, a heater can be provided on the outer surface of the permanent magnet 121 instead of heating the permanent magnet by activating the gradient amplifier as shown in FIG. 3. When the MRI system is not scanning, the temperature controller 116 controls the heater to heat the permanent magnet 121. In addition, when the MRI system shown in FIG. 2 is scanning, the heater can also be used to heat the permanent magnet 121 as required.

A simple comparison is made between the prior art MRI system and the MRI system according to the present invention by the tables below. Table 1 shows the heating estimation and the operating mechanisms of the prior art MRI system in different operating states. Table 2 shows the heating estimation and the operating mechanisms of the MRI system of the present invention in different operating states.

TABLE 1
(MRI system of the prior art)

| | | | | Heat needed | |
|---|---|---|---|---|---|
| | | | | for keeping | |
| | | | | the | |
| | | | | temperature | |
| | | | | of the MRI | |
| | Gradient | Power | Magnet | system | Temperature control |
| | coil | cabinet | heater | stable | mechanism |
| Scanning state | ~200 W | ~300 W | ~100 W | ~300 W | Controlling the on and off |
| | | | | | of the heater by a |
| | | | | | temperature control unit |
| | | | | | (usually including a |
| | | | | | temperature controller and |
| | | | | | a temperature sensor) |
| Standby state | 0 | 0 W | ~300 W | ~300 W | Controlling the on and off |
| | | | | | of the heater by the |
| | | | | | temperature control unit |

TABLE 2
(the MRI system according to the present invention)

| | | | | Heat needed | |
|---|---|---|---|---|---|
| | | | | for keeping | |
| | | | | the | |
| | | | | temperature | |
| | | | | of the MRI | |
| | Gradient | Power | Magnet | system | Temperature control |
| | coil | cabinet | heater | stable | mechanism |
| Scanning | ~200 W | ~300 W | none | ~300 W | Bringing heat from the power |
| state | | | | | cabinet to the external |
| | | | | | environment through a fan |
| Standby | ~100 W | ~200 W | none | ~300 W | The temperature controller |
| state | | | | | heat the permanent magnet by |
| | | | | | using the gradient amplifier in |
| | | | | | the power cabinet and the |
| | | | | | gradient coil unit in the |
| | | | | | magnetic field generating |
| | | | | | device based on the |
| | | | | | temperature sensor. The |
| | | | | | output current of said gradient |
| | | | | | amplifier is controlled |
| | | | | | according to the temperature |
| | | | | | feedback from the |
| | | | | | temperature sensor |

It can be seen from a comparison between table 1 and table 2 that the heat in the power cabinet is not used in the prior art MRI system, and a plurality of heaters have to be provided on the magnet to heat it. The MRI system according to the present invention makes full use of the heat produced in the power cabinet to heat the permanent magnet by arranging the power cabinet and the magnetic field generating device to be close to each other. Therefore the temperature control unit in the prior art MRI system is simplified, that is, there is no need to provide heaters on the magnet. Meanwhile, the heat produced by the power cabinet is transferred to the permanent magnet so as to cool the power cabinet per se, thus there is no need to provide a cooling system dedicated to the power cabinet and the noise is reduced accordingly. Therefore, compared to the prior art MRI system, the MRI system of the present invention simplifies the system structure, saves energy and improves the stability of the whole system.

It shall be noted that in the above descriptions about FIGS. 1-3, the division of the respective units is only for facilitating description. In fact, the division of the respective units that compose the MRI system can be changed. For example, the temperature controller 116, the cooling device 118, the heat sink 117 and the temperature sensor 124 can be separated from the power cabinet 110 and the magnetic field generating device 120 and be called by a general name of a temperature control unit of the host 100 of the MRI system, which is used to cool the power cabinet 110 of the host and to control the temperature of the main magnet 121 so as to keep it stable according to the operating mechanism as described previously.

In addition, it shall also be noted that in the above descriptions about FIGS. 1-3, the electronic components or devices in the power cabinet as listed are only the typical ones, and other electronic components or devices as needed by the MRI system may also be included. Moreover, some of the electronic components or devices listed in the power cabinet as shown in FIG. 3 can be placed out of the host 100 as required.

Furthermore, FIGS. 2 and 3 show the cable interfaces which represent all the cables needed for the connection between the respective electronic components of the power cabinet and the components of the magnetic field generating device, and the short lines at the right side of the cable interfaces represent different interfaces. Moreover, FIGS. 2 and 3 do not show all the connection relationship among the respective electronic components in the power cabinet, since such connection relationship is commonly known to those skilled in the art and omitted herein.

The above-mentioned embodiments illustrate rather than limit the invention. It shall be noted that those skilled in the art will conceive many improvements, modifications and variations to the present invention, so all such improvements, modifications and variations should be considered as falling within the scope of protection of this application without departing from the spirit of the present invention. The protection scope of the present invention is based on the appended claims. In addition, the present invention does not exclude that the embodiments in the claims can be combined to achieve better technical effect.

1. A magnetic resonance imaging system, comprising:
a display device; and
a host comprising:
a power cabinet comprising:
a gradient driver comprising a gradient controller and a gradient amplifier; and
a RF driver comprising a radio frequency (RF) controller and a RF amplifier; and
a magnetic field generating device comprising:
a pair of main magnets with opposite polarities that face each other and are spaced apart from each other;
a magnet column that forms a magnetic circuit for said main magnets; and
a gradient coil unit, wherein said power cabinet is provided adjacent to the outside of said magnet column of said magnetic field generating device, and wherein said power cabinet is configured to heat said main magnets by transferring heat produced in said power cabinet to said main magnets.

2. The magnetic resonance imaging system according to claim 1, wherein magnetic field sensitive components in said power cabinet are arranged far away from said magnetic field generating device, and high-power, magnetic field non-sensitive components in said power cabinet are arranged close to the outside of said magnet column.

3. The magnetic resonance imaging system according to claim 2, wherein said high-power, magnetic field non-sensitive components comprise a gradient amplifier and a RF amplifier.

4. The magnetic resonance imaging system according to claim 1, wherein said power cabinet further comprises a heat sink configured to transfer the heat produced in said power cabinet to said main magnets.

5. The magnetic resonance imaging system according to claim 4, wherein said heat sink is arranged along a side of said high-power, magnetic field non-sensitive components in said power cabinet that is close to said magnetic field generating device, such that the heat produced by operation of said high-power, magnetic field non-sensitive components is transferred to said main magnets through said heat sink.

6. The magnetic resonance imaging system according to claim 4, wherein said heat sink is arranged close to an outside surface of said magnet column.

7. The magnetic resonance imaging system according to claim 1, wherein a magnetic field strength at a rear end of said main magnets is limited within an acceptable range to reduce an influence to electronic components in said power cabinet by a magnetic field of said main magnets.

8. The magnetic resonance imaging system according to claim 1, wherein said magnetic field generating device further comprises a temperature monitoring means configured to detect a temperature of said main magnet, and said power cabinet further comprises a temperature controller and a cooling device, wherein said temperature controller is configured to selectively activate and deactivate said cooling device according to the temperature provided by said temperature monitoring means such that said cooling device is activated to dissipate the heat in said power cabinet and said magnetic field generating device out of said host when said main magnets do not need to be heated and said cooling device is deactivated when said main magnets need to be heated.

9. The magnetic resonance imaging system according to claim 8, wherein said temperature monitoring means comprises a temperature sensor inserted into said main magnets.

10. The magnetic resonance imaging system according to claim 8, wherein:
said temperature controller is connected to said gradient amplifier to selectively activate and deactivate said gradient amplifier according to the temperature provided by said temperature monitoring means when said magnetic resonance imaging system is in a non-operating state, and when said main magnets need to be heated, said temperature controller is configured to activate said gradient amplifier so that the heat generated by operation of said gradient amplifier is transferred to said main magnets, and said gradient amplifier supplies electric current to the gradient coil unit to make it operate so that the heat produced by operation of the gradient coil unit is also used to heat the main magnet; and
when said main magnets do not need to be heated, said temperature controller are configured to cause said gradient amplifier to stop operating.

11. The magnetic resonance imaging system according to claim 8, wherein:
during operation of said MRI system, when said temperature controller determines that said main magnets need to be heated according to the temperature transferred from said temperature monitoring means, the heat produced by operation of said gradient amplifier and said RF amplifier is transferred to said main magnets; and
when said temperature controller determines that said main magnets do not need to be heated, said cooling device is configured to dissipate the heat produced by operation of said gradient amplifier and said RF amplifier as well as the heat in said magnetic field generating device out of said host.

12. A method for stabilizing a main magnet temperature in a magnetic resonance imaging system, wherein the magnetic resonance imaging system includes a power cabinet and a magnetic field generating device, the power cabinet includes a gradient driver including a gradient controller and a gradient amplifier and a RF driver including a RF controller and a RF amplifier, and the magnetic field generating device includes a pair of main magnets with opposite polarities that face each other and are spaced apart from each other, a magnet column that forms a magnetic circuit for the main magnets and a gradient coil unit, said method comprising:
arranging the power cabinet to be adjacent to the outside of the magnet column of the magnetic field generating device, such that heat produced in the power cabinet is transferred to the main magnets.

13. The method according to claim 12, wherein magnetic field sensitive components in the power cabinet are arranged far away from the magnetic field generating device, high-power, magnetic field non-sensitive components in the power cabinet are arranged close to the outside of the magnet column.

14. The method according to claim 13, wherein the high-power, magnetic field non-sensitive components are a gradient amplifier and a RF amplifier.

15. The method according to claim 12, wherein the heat produced in the power cabinet is transferred to the main magnets through a heat sink.

16. The method according to claim 15, wherein the heat sink is arranged at a side of the high-power, magnetic field non-sensitive components in the power cabinet that is close to the magnetic field generating device, such that the heat produced by operation of the high-power, magnetic field non-sensitive components can be transferred to the main magnets through the heat sink.

17. The method according to claim 15, wherein the heat sink is arranged close to the outside surface of the magnet column.

18. The method according to claim 12, wherein a magnetic field strength at a rear end of the main magnets is limited within an acceptable range to reduce an influence to electronic components in the power cabinet by the magnetic field.

19. The method according to claim 12, wherein when the magnetic resonance imaging system is in a non-operating state, a temperature of the main magnets is monitored, and when the main magnets need to be heated, the gradient amplifier is activated so that the heat produced thereby is transferred to the main magnets, and the gradient amplifier supplies electric current to the gradient coil unit so that the heat produced by operation of the gradient coil unit is also used to heat the main magnets, and wherein when the main magnets do not need to be heated, the gradient amplifier stops operating.

20. The method according to claim 12, wherein during the operation of the magnetic resonance imaging system, the heat produced by operation of the gradient amplifier and the RF amplifier is transferred to the main magnets when the main magnets need to be heated, and the heat produced by operation of the gradient amplifier and the RF amplifier as well as the heat in the magnetic field generating device is dissipated out of the magnetic resonance imaging system when the main magnets do not need to be heated.
